(19) United States
(12) Patent Application Publication
(10) Pub. No.: US 2008/0245412 A1
(43) Pub. Date: Oct. 9, 2008

(54) Cover For Solar Cells

(75) Inventor: Jurgen Uehlin, Schopfheim (DE)

Correspondence Address: VOLPE AND KOENIG, P.C., UNITED PLAZA, SUITE 1600, 30 SOUTH 17TH STREET, PHILADELPHIA, PA, 19103, US

(73) Assignee: DURLUM-LEUCHTEN GMBH LICHTTECHNISCHE SPEZIALFABRIK, Schopfheim (DE)

(21) Appl. No.: 12/093,400

(22) PCT Filed: Nov. 14, 2006
(86) PCT No.: PCT/DE2006/001995

§ 371 Date: May 12, 2008

(30) Foreign Application Priority Data
Nov. 15, 2005 (DE) 10 2005 054 365.0

(51) Int. Cl. H01L 31/00

(52) U.S. Cl. 136/259

(57) ABSTRACT

A method for shading solar cells that are exposed to concentrated radiation is provided in order to avoid overheating.

### BACKGROUND

The present invention relates to a solar collector essentially comprising solar cells mounted to carriers that can be cooled.

Such photovoltaic modules serve to directly convert solar radiation. The spectrum of electromagnetic radiation emitted by the sun can only be used to a limited extent, because the sensitivity of the solar cells is given only in the range from approximately 350-900 nm. The energy of the UV-radiation below 350 nm and the infrared radiation above 900 nm only results in heating the cells. Their effectiveness is at a maximum at temperatures about −20° C., and on and above 80° C. it is so low that any production of electricity is no longer profitable. At even higher temperatures the cells can be destroyed, with the values largely depending on the respective type of solar cells.

This problem drastically increases when the solar cells are operated with concentrated light. At a concentration factor of 10 a few minutes (of sunshine) on a clear summer's day are sufficient to reach temperatures that will have destructive effects. The cells must be cooled.

In prior art, it is attempted to dissipate the heat either via large-area cooling elements or to connect the solar cells and/or their carriers with a cooling element with a refrigerant flowing through it. It is also known to allow a refrigerant to flow around the solar cells in order to improve the heat transfer, with multiple problems occurring with regard to corrosion and short circuit proofing and a considerable portion of the electric energy generated by the cells must be used for the operation of the circulating pump of the refrigerant.

### SUMMARY

The object of the invention is to provide a cooling method, which can be produced easily and at low cost and protects the solar cells from overheating.

The object is attained according to the invention such that in the radiation path, preferably between the concentrator and the solar cells, a transparent cover element is interposed, which is provided with electro-chromic and/or thermo-tropic and/or phototropic and/or photoelectro-chromic and/or photo-chromic features.

These features are provided by the so-called switchable glass, which is also used in architectural glass. Day light and solar heat can be reduced by the use of switchable glass. Glass tinting due to solar radiation is known, for example, in the form of self-tinting sun glasses. Their photoelectro-chromic layers tint gray or brown under solar radiation, however they remain clear. The switchable layers are differentiated depending on activation and structure. Any tinting (e.g., blue coloration) can occur by an electric current (electro-chromic layers), contact with a gas (gas-chromic layers), radiation (solar radiation), or by heat. The so-called thermo-chromic or thermo-tropic layers, when exceeding a certain temperature limit of the material, cause a change of color or a white cloudiness. With switchable mirrors on a metal-hydride basis the light permeability is increased with the help of hydrogen gas. Electric voltage clears the layers of light diffusing glass, which are produced based on liquid crystals or polarized particles.

The light diffusion reduces the solar energy input and thus diminishes the thermal stress of the solar cells.

When using electro-chromic glass an additional device is to be provided, controlling the level of radiation permeability of the glass. Here, the desired effect of protection from the sun can occur automatically by temperature sensors controlling the permeability of the glass via a control device. Unlike electro-chromic glass, in which the change of energy permeability is caused by electric fields, phototropic glass tints under the influence of the UV-radiation of sunlight and thermo-tropic glass depending on temperature but not on light intensity.

When the switchable glass on the side facing the sun is additionally provided with a layer reflecting infrared radiation the heat stress is reduced by approximately 35%. Additionally the side facing away from the sun may also be provided with a coating blocking UV-radiation, which reflects approximately 15% of the heat radiation.

### BRIEF DESCRIPTION OF THE DRAWINGS

In the following, the invention is described schematically using the attached drawing. Shown is:

### DETAILED DESCRIPTION OF THE PREFERRED EMBODIMENT

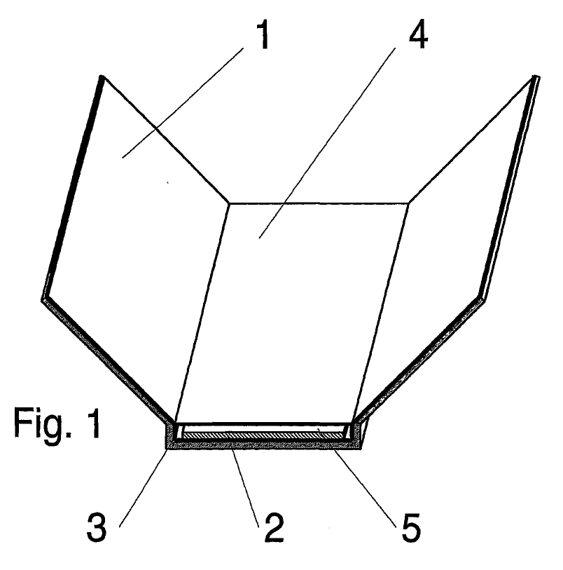

FIG. 1 shows, in a horizontal cross-section, a solar collector with concentrators 1, which are arranged mirror-inverted alongside the solar cells. The light perpendicularly impinging the reflective surfaces of the concentrators 1 is reflected to the solar cells 2 and concentrated. The carrier 3 stabilizes and fixes the entire module. The transparent cover element 4 is mounted above the solar cells 2, provided with electro-chromic and/or thermo-tropic and/or photo-tropic and/or photoelectron-chromic and/or photo-chromic features, together with the carrier 3 forming the hollow space 5. This hollow space 5 can be sealed hermetically and/or filled with a refrigerant, or be open and/or ventilated. When using electro-chromic glass the sensors and/or the control devices can be arranged in this hollow space 5. When the cover element 4 is equipped with additional filter layers it is advantageous for the UV-protective layer to be provided at the side facing the solar cells and the IR-protective layer at the opposite side, because otherwise the long-wave radiation heats the glass.

1. A method for shading solar cells radiated with concentrated sunlight, comprising interposing a transparent cover element in a radiation path in order to avoid overheating the solar cells, and the transparent cover element is provided with at least one of electro-chromic, and/or thermo-tropic, photo-tropic or photoelectro-chromic features.

2. A method according to claim 1, further comprising providing the cover element with a layer that reflects of infrared or UV-radiation.

3. A method according to claim 1, further comprising controlling radiation permeability via temperature sensors and a control device.

4. A method according to claim 1, wherein the transparent cover element is interposed between a concentrator and the solar cells.
